(19) United States
(12) Patent Application Publication
(10) Pub. No.: US 2026/0360669 A1
(43) Pub. Date: Nov. 12, 2026

(54) Liquid-Cooled Conductor Structure and RF Plasma Impedance Matching System

(71) Applicant: Rohde & Schwarz GmbH & Co. KG, Muenchen (DE)

(72) Inventors: Mathias Pietzka, Muenchen (DE); Adrian Fruehauf, Muenchen (DE); Alexander Meixner, Muenchen (DE); Wolfgang Wanninger, Muenchen (DE); Gabor Czobor, Muenchen (DE); Dirk Fehse, Muenchen (DE)

(21) Appl. No.: 19/202,931

(22) Filed: May 8, 2025

(51) Int. Cl. H01J 37/32

(52) U.S. Cl. CPC H01J 37/32183; H01J 37/32541; H01J 2237/002

(57) ABSTRACT

A liquid-cooled conductor structure for a radio frequency (RF) plasma impedance matching network is described. The liquid-cooled conductor structure comprises at least one hollow conductor that comprises an electrically conductive material. The at least one hollow conductor has a first end portion and a second end portion. The first end portion is electrically connectable to the impedance matching network, and the second end portion is electrically connectable to the impedance matching network. The liquid-cooled conductor structure has a first fluid port and a second fluid port that are both fluidly connected to the at least one hollow conductor, such that a liquid cooling agent can flow through the first fluid port, the at least one hollow conductor, and the second fluid port.

### FIELD OF THE DISCLOSURE

Embodiments of the present disclosure generally relate to a liquid-cooled electrical conductor structure for a radio frequency, RF, plasma impedance matching network. Embodiments of the present disclosure further relate to an RF plasma impedance matching system.

### BACKGROUND

The generation of low-temperature plasmas is often realized by applying RF power into a gas filled process chamber, such that the gas atoms are ionized and a plasma is established.

The ignition and maintenance of the plasma requires a matching of the RF source impedance to the plasma impedance which can be within a large impedance range depending on gas type, process chemistry, etc. For this purpose, an impedance matching network is placed into the RF chain between the RF signal generator and the process chamber.

The RF impedance matching network is, of course, subject to electrical losses, which may require the RF impedance matching network to be cooled actively.

An approach known in the state of the art is to provide air cooling for the RF impedance matching network. For this purpose, fans may be provided, which can be prone to mechanical failure. Moreover, due to the airflow, outgassing from electrical parts of the impedance matching network can be distributed into the environment, or dust from the environment can be introduced into the impedance matching network.

Thus, there is a need for a conductor structure as well as for an RF plasma impedance matching system that are more reliable and prevent unintentional contamination.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a liquid-cooled conductor structure for a radio frequency (RF) plasma impedance matching network. In an embodiment, the liquid-cooled conductor structure comprises, for example, at least one hollow conductor that comprises an electrically conductive material. The at least one hollow conductor has a first end portion and a second end portion. The first end portion is electrically connectable to the impedance matching network and the second end portion is electrically connectable to the impedance matching network. The liquid-cooled conductor structure has a first fluid port and a second fluid port that are both fluidly connected to the at least one hollow conductor such that a liquid cooling agent can flow through the first fluid port, the at least one hollow conductor, and the second fluid port. The at least one hollow conductor provides at least two separate fluid path portions for the liquid cooling agent. Both the first fluid port and the second fluid port are arranged at the first end portion of the at least one hollow conductor.

The term “electrically connect” is understood to denote that a direct connection via an electrical conductor is established.

The conductor structure mentioned may generally relate to an electrical conductor structure.

The liquid-cooled conductor structure according to embodiments of the present disclosure is based on the idea to provide a liquid-based cooling for at least a portion of the RF plasma impedance matching network instead of an air-based cooling. This is achieved, for example, by providing the at least one hollow conductor, the first fluid port and the second fluid port.

In one or more embodiments, a fluid path is established within the liquid-cooled conductor structure, wherein the fluid path extends through the first fluid port, the at least one hollow conductor, and the second fluid port.

Thus, heat generated due to electric losses in the at least one hollow conductor can be conducted away by the liquid cooling agent flowing through the fluid path.

Accordingly, no air flow is necessary in order to cool the RF plasma impedance matching network, which prevents unwanted contamination of both the RF plasma impedance matching network and the environment of the RF plasma impedance matching network.

In an embodiment, the liquid-cooled conductor structure is suitable for clean room applications.

In an embodiment, the liquid cooling agent may flow from the first fluid port to the second fluid port or vice versa.

In an embodiment, the at least two separate fluid path portions comprise a first fluid path portion, which corresponds to a fluid flow from the first end portion of the at least one hollow conductor to the second end portion of the at least one hollow conductor.

In an embodiment, the at least two separate fluid path portions comprise a second fluid path portion that corresponds to a fluid flow from the second end portion of the at least one hollow conductor to the first end portion of the at least one hollow conductor.

In an embodiment, both fluid path portions may be provided within the same at least one hollow conductor, or within different hollow conductors, as will be described in more detail below.

In one or more embodiments, the fluid path portions are structurally separate, i.e. the fluid path portions provided by the at least one hollow conductor do not merge into each other immediately.

In an embodiment, first fluid port and the second fluid port are both arranged on the same side of the at least one hollow conductor, namely at the first end portion of the at least one hollow conductor.

When electrically connecting the first end portion(s) of the at least one hollow conductor to the impedance matching network, the first end portion(s) and thus the first fluid port and the second fluid port may be arranged at a side having lower electrical potential, thereby reducing the risk of insulation issues.

In an embodiment, the first fluid port and the second fluid port may both be arranged at the side having a lower potential difference to a reference potential. For example, the reference potential may be a ground potential or any other suitable reference potential.

Put differently, the liquid-cooled conductor structure according to embodiments of the present disclosure establishes an electrical two-gate and a fluid two-gate, wherein both gates of the fluid two-gate are arranged on the same side of the electrical two-gate, namely at a first electrical gate of the electrical two-gate. The other side of the electrical two-gate, namely the side of a second electrical gate, is free from fluid gates.

It is noted that the at least one hollow conductor may comprise or consist of, for example, any suitable electrical conductive material. Therein, an electrically conductive material may be chosen that has both high electrical conductivity and thermal conductivity.

The liquid-cooled conductor structure may have other suitable applications. For example, another application for the liquid-cooled conductor structure may relate to an antenna tuning unit, e.g. besides the RF plasma impedance matching network. In other words, embodiments of the present disclosure may relate to a liquid-cooled conductor structure for a radio frequency (RF) plasma impedance matching network, an antenna tuning unit, or other arrangements that would benefit from the heat transfer properties of the liquid-cooled conductor structure.

According to an aspect of the present disclosure, the at least one hollow conductor, for example, establishes an inductance. In an embodiment, the at least one hollow conductor may establish the inductance due to its shape.

For example, the at least one hollow conductor may have a spiral shape, a planar shape, or a cylindrical shape. However, it is to be understood that the at least one hollow conductor may have any other suitable shape.

In an example embodiment of the present disclosure, the liquid-cooled conductor structure comprises at least two separately formed hollow conductors that are arranged in parallel. Accordingly, the at least two separate fluid path portions may be established by different hollow conductors Each hollow conductor, for example, has a wall delimiting the flow path for the cooling agent to the exterior. However, the walls of the different hollow conductors do not merge into each other directly. Instead, a fluid redirecting portion may be provided, wherein the fluid redirecting portion fluidly connects the second end portions of the hollow conductors.

In a further embodiment, the at least one hollow conductor comprises a separating wall within the at least one hollow conductor for establishing the separate fluid path portions. Accordingly, the separate fluid path portions may be established by a single hollow conductor, wherein the separating wall separates the fluid path portions.

In an embodiment, the separating wall may be shorter than an outer wall of the hollow conductor, thereby establishing an internal redirecting section that connects both separate fluid path portions with each other. The first fluid path portion may be encompassed by the separating wall, e.g. established by a pipe, a tube, a sleeve or a hose that is inserted into the hollow conductor, so as to separate the first fluid path portion from the remainder that establishes the second fluid path portion. Since the separating wall, namely the inserted pipe, tube, sleeve or hose, is shorter compared to the outer wall of the hollow conductor, the cooling agent may be redirected internally.

According to another aspect of the present disclosure, the electrically conductive material comprises, for example, at least one electrically conductive metal. Therein, a metal or metal alloy having both high electrical conductivity and thermal conductivity may be used.

In a further embodiment, the at least one electrically conductive metal comprises copper. Copper has both high electrical conductivity and thermal conductivity, and is thus particularly suitable for the at least one hollow conductor.

An aspect of the present disclosure provides, for example, that the at least one electrically conductive material comprises at least one electrically conductive non-metallic material. Therein, a non-metallic material or combination of materials having both high electrical conductivity and thermal conductivity may be used.

In an example embodiment, the at least one electrically conductive non-metallic material is diamagnetic or paramagnetic. Accordingly, the at least one electrically conductive non-metallic material is not ferromagnetic, and has low magnetic permeability.

In another embodiment, an inner surface of a wall of the at least one hollow conductor comprises a protective layer. The protective layer allows to use certain cooling agents such as de-ionized water, which can be corrosive for certain metallic materials, for example for copper, or for other metal (alloys) having high electrical conductivity.

In an embodiment, the protective layer may be coated onto the at least one hollow conductor. Alternatively, the protective layer may be provided first, and an electrically conductive layer may be coated onto the protective layer, thereby forming the at least one hollow conductor.

In general, a material having chemical resistance to the cooling agent to be used may be chosen for the protective layer. A material also having high thermal conductivity may be chosen for the protective layer.

For example, the protective layer comprises at least one of plastic, stainless steel, or lacquer. However, it is to be understood that any other suitable type of material may be used for the protective layer.

Embodiments of the present disclosure further provide a radio frequency (RF) plasma impedance matching system. In an embodiment, the RF plasma impedance matching system comprises an RF plasma impedance matching network. The RF plasma impedance matching network comprises an input port being connectable to a radio frequency, RF, generator circuit. The RF plasma impedance matching network further comprises an output port being connectable to a load. The RF plasma impedance matching network further comprises a transmission circuit, wherein the transmission circuit connects the output port to the input port. The RF plasma impedance matching network comprises at least one liquid-cooled conductor structure described above.

In an embodiment, the transmission circuit may comprise at least one liquid-cooled conductor structure according to any one of the embodiments described above.

Regarding the further advantages and properties of the RF plasma impedance matching system, reference is made to the explanations given above with respect to the liquid-cooled conductor structure, which also hold for the RF plasma impedance matching system and vice versa.

In an embodiment, the RF plasma impedance matching system may further comprise an RF generator circuit. The RF generator circuit comprises a heat sink and the impedance matching system further comprises a first cooling agent tube being connected to the first fluid port and a second cooling agent tube being connected to the second fluid port, and wherein at least one of the first cooling agent tube or the second cooling agent tube is directly connected to the heat sink. Thus, the heat sink of the RF generator circuit can be used for discharging heat from the RF plasma impedance matching network, for example from the at least one hollow conductor.

Accordingly, no additional heat sink is required for cooling the RF plasma impedance matching network, which makes the RF plasma impedance matching system both more cost-efficient and less complicated.

For example, the heat sink may be or comprise a plate, for example a metal plate, a radiator, or any other suitable type of heat sink.

In an example embodiment of the present disclosure, the first cooling agent tube and the second cooling agent tube each comprising, or alternatively, consisting of an electrically isolating material at least partially. Thus, the at least one hollow conductor is electrically isolated from the heat sink, such that unwanted currents and/or voltages between the at least one hollow conductor and the heat sink are prevented.

In an embodiment, the cooling agent tubes may comprise or consist of any suitable material being electrically insulating and thermally stable in temperature regions reached by the cooling agent during operation. For example, the cooling agent tubes may comprise or consist of plastic, such as PEEK, PEK, PPS, PI, PEI, etc.

In a further embodiment, the RF plasma impedance matching system further comprise at least one electrical isolator. The at least one electrical isolator is configured to electrically isolate the at least one hollow conductor from the heat sink. Thus, undesired currents and/or voltages between the at least one hollow conductor and the heat sink are prevented by the at least one electrical isolator.

As already described above, the at least one electrical isolator may be established by the cooling agent tubes.

An aspect of the present disclosure provides that the RF plasma impedance matching network comprises, for example, a housing. In an embodiment, the transmission circuit is arranged within the housing.

In an embodiment, the housing may be fully closed. In other words, the housing may not comprise any air inlets or air outlets, such holes or grids. Thus, an undesired contamination of both the RF plasma impedance matching network and the environment of the RF plasma impedance matching network is prevented.

In an example embodiment, the housing is air-tight. Thus, undesired contaminations of both the RF plasma impedance matching network and the environment of the RF plasma impedance matching network are prevented particularly efficiently, which is particularly important for clean room applications.

According to another aspect of the present disclosure, the at least one hollow conductor, for example, is electrically connected to the transmission circuit via clamping of a strip or wire of the transmission circuit to the at least one hollow conductor.

In another embodiment, the at least one hollow conductor is electrically connected to the transmission circuit via soldering of a strip or wire of the transmission circuit to the at least one hollow conductor. However, it is to be understood that any other suitable type of electrically conductive connection may be used in order to electrically connect the at least one hollow conductor to the transmission circuit.

An aspect of the present disclosure provides that the first fluid port and the second fluid port both are, for example, arranged at a side of the liquid-cooled conductor structure having a lower potential difference to a reference potential. Thereby, insulation issues are avoided reliably. For example, the reference potential may be a ground potential or any other suitable reference potential

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a plasma control system according to an embodiment of the present disclosure;

FIG. 2 schematically shows an example embodiment of an impedance matching network of the plasma control system of FIG. 1;

FIG. 3 schematically shows an example of a liquid-cooled conductor structure of the impedance matching network of FIG. 2;

FIG. 4 schematically shows a portion of the plasma control system comprising an RF generator circuit and the liquid-cooled conductor structure;

FIG. 5 schematically shows a first embodiment of a portion of the liquid-cooled conductor structure;

FIG. 6 schematically shows a second embodiment of a portion of the liquid-cooled conductor structure;

FIG. 7 schematically shows a third embodiment of a portion of the liquid-cooled conductor structure;

FIG. 8 schematically shows a fourth embodiment of a portion of the liquid-cooled conductor structure;

FIG. 9 schematically shows a fifth embodiment of a portion of the liquid-cooled conductor structure;

FIG. 10 schematically shows a sixth embodiment of a portion of the liquid-cooled conductor structure;

FIG. 11 schematically shows a seventh embodiment of a portion of the liquid-cooled conductor structure; and

FIG. 12 schematically shows a cross sectional view along the length of the liquid-cooled conductor structure according to any of the embodiments shown in FIGS. 8-11.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

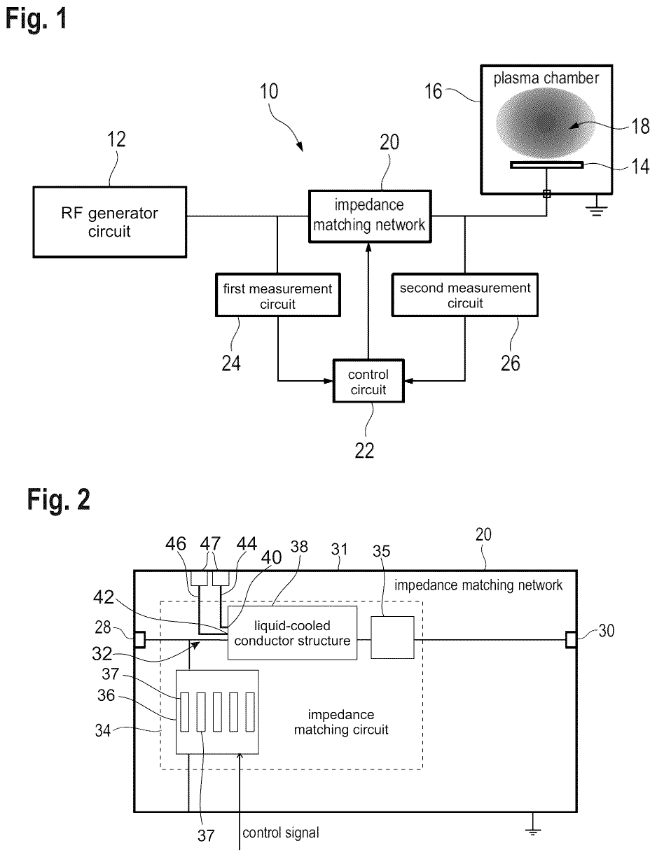

FIG. 1 schematically shows a plasma control system 10 that comprises an RF generator circuit 12 and a chamber feed unit 14, wherein the chamber feed unit 14 is located in a plasma chamber 16. In general, the RF generator circuit 12 is configured to generate an RF signal that is forwarded to the chamber feed unit 14. The chamber feed unit 14 feeds the RF signal into plasma 18 contained in the plasma chamber 16, thereby initiating and/or maintaining the plasma 18. For example, the chamber feed unit 14 may be an electrode generating an electric field or an inductive coil generating a magnetic field.

In order to minimize losses and maximize the amount of energy fed into the plasma 18, the plasma control system 10 comprises an impedance matching network 20. In an embodiment, the impedance of the impedance matching network 20 can be adapted in order to account for a varying impedance of the plasma 18. For example, the impedance matching network 20 is interconnected between the RF generator circuit 12 and the chamber feed unit 14, such that the impedance of a load presented to the RF generator circuit 12 can be adapted by the impedance matching network 20. The impedance of the impedance matching network 20 is controlled by a control circuit 22.

In general, the control circuit 22 controls the impedance matching network 20 based on at least one first measurement parameter obtained by a first measurement circuit 24 and based on at least one second measurement parameter obtained by a second measurement circuit 26. The first measurement circuit 24 receives an input signal of the impedance matching network 20 and determines the at least one first measurement parameter based on the input signal of the impedance matching network 20. In an embodiment, the input signal of the impedance matching network 20 corresponds to the RF signal generated by the RF generator circuit 12.

The second measurement circuit 26 receives an output signal of the impedance matching network 20 and determines the at least one second measurement parameter based on the output signal of the impedance matching network 20. The output signal of the impedance matching network 20 corresponds to the RF signal generated by the RF generator circuit 12 and processed by the impedance matching network 20.

FIG. 2 schematically shows an example embodiment of the impedance matching network 20 in more detail. As shown in the embodiment of FIG. 2, the impedance matching network 20 comprises an input port 28 that is connected to the RF generator circuit 12. The impedance matching network 20 further comprises an output port 30 that is connected to the chamber feed unit 14.

In an embodiment, the impedance matching network 20 may comprise a housing 31, wherein the input port 28 and the output port 30 may be provided in a wall or in walls of the housing 31. Between the input port 28 and the output port 30, a transmission circuit having a transmission line 32 is provided that connects the input port 28 to the output port 30.

In general, the impedance matching network 20 is configured to forward the RF signal generated by the RF generator circuit 12 from the input port 28 to the output port 30 while matching an impedance presented to the RF generator circuit 12. In an embodiment, the impedance matching network 20 comprises an impedance matching circuit 34.

In general, the impedance matching circuit 34 is configured to selectively couple at least one reactance to and/or into the transmission line 32. In an embodiment, the at least one reactance may comprise at least one capacitance and/or at least one inductance. For example, the at least one reactance may comprise a plurality of capacitances and/or a plurality of inductances. In the example embodiment shown in FIG. 2, the impedance matching circuit 34 is interconnected between the input port 28 and the output port 30 as well as a common impedance matching circuit 34.

In an embodiment, the impedance matching network 20 may comprise at least one further reactance 35 that is provided in the transmission line 32, for example as part of the impedance matching circuit 34. For example, the at least one further reactance 35 may be a capacitor.

In an embodiment, the impedance matching circuit 34 comprises a first part 36, for instance a reactance unit having at least one reactance, for example several capacitances 37. The first part 36 is interconnected between a contact point to the transmission line 32 and the common reference potential. Accordingly, the impedance matching circuit 34 is configured to selectively couple the at least one reactance, for example at least one of the several capacitances 37, between the transmission line 32 and the common reference potential. In an example, the common reference potential may be a ground potential.

However, it is to be understood that the impedance matching circuit 34 may alternatively be provided (only) in the transmission line 32, wherein the impedance matching circuit 34 may be interconnected between the input port 28 and the output port 30.

In this case, the impedance matching circuit 34 may be configured to selectively couple the at least one reactance into the transmission line 32 between the input port 28 and the output port 30.

According to another embodiment, the impedance matching circuit 34 may be provided (only) between the contact point to the transmission line 32 and the common reference potential.

Moreover, it is to be understood that further impedance matching circuits may be provided in an arbitrary topology. For example, the impedance matching circuits of the impedance matching network 20 may be arranged according to a T-topology, an L-topology, or a T-topology.

In an embodiment, the impedance matching circuit 34, for example the first part 36, may receive a control signal from the control circuit 22, wherein the control signal controls the impedance matching circuit 34, for example the first part 36, to adapt its impedance.

As is schematically illustrated in FIG. 2, the impedance matching network 20 further comprises at least one liquid-cooled conductor structure 38 that forms a second part of the impedance matching circuit 34 as will be described later. In the example embodiment shown in FIG. 2, the liquid-cooled conductor structure 38 is located in the impedance matching circuit 34.

In an embodiment, the liquid-cooled conductor structure 38 may be connected to the input port 28 directly, i.e. without further components being provided between the input port 28 and the liquid-cooled conductor structure 38, in order to ensure an appropriate voltage being applied to the liquid-cooled conductor structure 38.

In an embodiment, the at least one further reactance 35 may be provided downstream of the liquid-cooled conductor structure 38.

However, it is to be understood that the liquid-cooled conductor structure 38 may be arranged in a different impedance matching circuit.

In an embodiment, the liquid-cooled conductor structure 38 comprises a first fluid port 40 and a second fluid port 42, as well as a first fluid line 44 and a second fluid line 46. The first fluid port 40 and the second fluid port 42 are both arranged at the side of the liquid-cooled conductor structure 38 having lower potential difference to the common reference potential, i.e. at the side of the liquid-cooled conductor structure 38 facing the input port 28.

In an embodiment, the potential difference to the common reference potential at the side facing the input port 28 may be several times smaller than the potential difference to the common reference potential at the side facing the output port 30, for example at least five times smaller or at least ten times smaller.

In a particular example, the potential difference may be about 200 V at the side of the liquid-cooled conductor structure 38 facing the input port 28, and about 5 kV at the side of the liquid-cooled conductor structure 38 facing the output port 38.

In the example embodiment shown in FIG. 2, fluid connector ports 47 are provided in a wall of the housing 31 that are connected to the first fluid port 40 and the second fluid port 42 via the first fluid line 44 and the second fluid line 46, respectively. The fluid connector ports 47 may also be arranged on the side of the liquid-cooled conductor structure 38 having lower potential difference to the common reference potential.

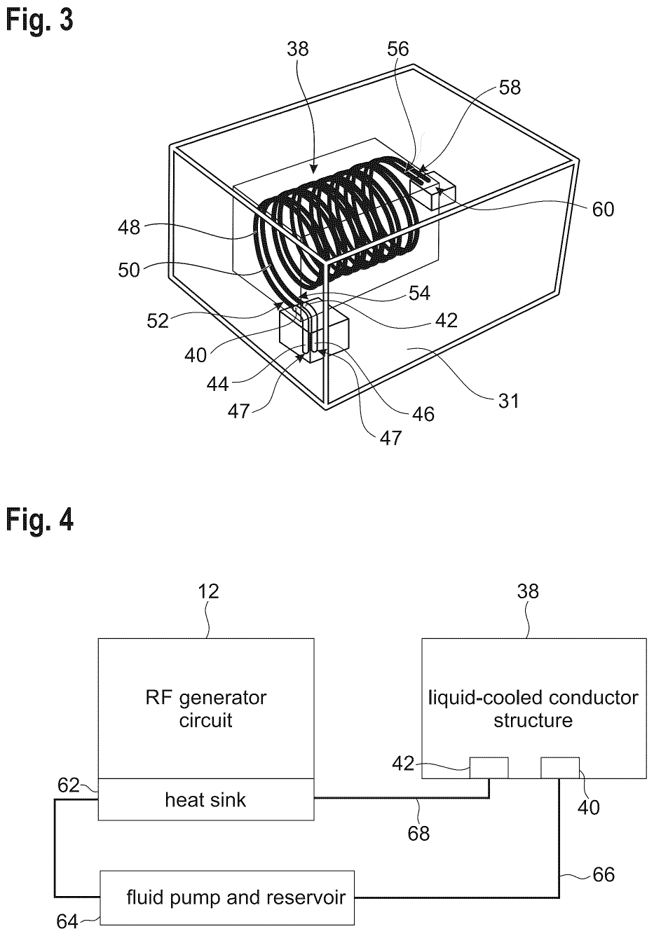

FIG. 3 schematically shows an example of the liquid-cooled conductor structure 38 in more detail. In the example embodiment shown in FIG. 3, the liquid-cooled conductor structure 38 comprises a first hollow conductor 48 and a second hollow conductor 50, wherein the first hollow conductor 48 and the second hollow conductor 50 are formed separately.

In general, the first hollow conductor 48 and the second hollow conductor together establish an inductance, for example due to the shape of the hollow conductors 48, 50. In the example embodiment shown in FIG. 3, the first hollow conductor 48 and the second hollow conductor 50 are arranged in parallel and in a spiral shape, such that the hollow conductors 48, 50 establish a coil. Accordingly, the hollow conductors 48, 50 of the liquid-cooled conductor structure 38 establish the second part of the impedance matching circuit 34, as already indicated above. However, it is to be understood that the hollow conductors 48, 50 may have any other suitable shape establishing an inductance.

In an embodiment, the first hollow conductor 48 comprises a first end portion 52 that is fluidly connected to the first fluid port 40. Likewise, the second hollow conductor 50 comprises a first end portion 54 that is fluidly connected to the second fluid port 42.

The first hollow conductor 48 further comprises a second end portion 56 that is arranged at an end of the first hollow conductor 48 opposite the first end portion 54. Likewise, the second hollow conductor 50 further comprises a second end portion 58 that is arranged at an end of the second hollow conductor 50 opposite to the first end portion 56.

At the second end portions 54, 58 of the hollow conductors 48, 50, a fluid redirecting portion 60 is provided that is fluidly connected to both second end portions 54, 56. For example, the redirecting portion 60 may be established as tube that is separate from the hollow conductors 48, 50. For example, the tube may comprise or consist of a metal or a plastic, such as PEEK, PEK, PPS, PI, PEI, etc. It is easier to connect the hollow conductors 48, 50 with the redirecting portion 60 in case the tube comprises or consists of a metal. It is to be understood that the redirecting portion 60 may be established in any other suitable way.

However, it is emphasized that the fluid redirecting portion 60 is established separately from the hollow conductors 48, 50, i.e. the fluid redirecting portion 60 is established neither by the first hollow conductor 48 nor by the second hollow conductor 50. In other words, the fluid redirecting portion 60 does not relate to a bent portion of a single hollow conductor.

In an embodiment, a fluid path for a cooling agent is established between the fluid connector ports 47 by the first fluid line 44, the first fluid port 40, the first hollow conductor 48, the fluid redirecting portion 60, the second hollow conductor 50, the second fluid port 42, and the second fluid line 46, wherein the cooling agent may flow from the first fluid port 40 to the second fluid port 42, or from the second fluid port 42 to the first fluid port 40.

In an embodiment, the cooling agent flows on the inside of the hollow conductors 48, 50. Accordingly, the first hollow conductor 48 establishes a first fluid path portion, namely between the first fluid line 44 and the fluid redirecting portion 60, while the second hollow conductor 50 establishes a second fluid path portion between the second fluid line 46 and the fluid redirecting portion 60.

Accordingly, the fluid path portions provided by the hollow conductors 48, 50 are separated from each other by the fluid redirecting portion 60 that is provided separately from the hollow conductors 48, 50.

In general, the liquid-cooled conductor structure 38 is configured to discharge heat generated due to electric losses in the inductance formed by the hollow conductors 48, 50. The heat is transported away by the liquid cooling agent flowing through the hollow conductors 48, 50.

As the heat is discharged via the liquid-cooled conductor structure 38, the housing 31 may be fully closed. In an embodiment, the housing 31 may be airtight.

FIG. 4 shows an example embodiment of how the heat can be discharged from the impedance matching network. In this embodiment, the RF generator circuit 12 comprises a heat sink 62, which may, for example, be established as a plate, for example a metal plate, a radiator, or any other suitable type of heat sink.

In an embodiment, the plasma control system 10 further comprises a fluid pump and reservoir 64 that is fluidly connected to the heat sink 62. The first fluid port 40 is fluidly connected to the fluid pump and reservoir 64 by a first cooling agent tube 66. The second fluid port 42 is fluidly connected to the heat sink 62 by a second cooling agent tube 68.

It is noted that the fluid connector ports 47 and the fluid lines 44, 46 are not shown in FIG. 4. In the example embodiment shown in FIGS. 2 and 3, the cooling agent tubes 66, 68 may be connected to the fluid connector ports 47, and the fluid ports 40, 42 may be connected to the fluid connector ports 47 via the fluid lines 44, 46.

In an embodiment, a fluid path is established from the fluid pump and reservoir 64 through the first cooling agent tube 68, the first fluid port 40, the first hollow conductor 48, the second hollow conductor 50, the second fluid port 42, the second cooling agent tube 68, the heat sink 62, and back to the fluid pump and reservoir 64. Accordingly, heat generated in the inductance formed by the hollow conductors 48, 50 can be discharged via the heat sink 62 of the RF generator circuit 12.

It is to be understood that it is not necessary to use the heat sink 62 of the RF generator circuit 12. Alternatively, a dedicated heat sink may be provided, or a heat sink of a different component may be used to discharge the heat generated in the inductance formed by the hollow conductors 48, 50.

In an embodiment, the cooling agent tubes 66, 68 may comprise or consist of any suitable material being electrically insulating and thermally stable in temperature regions reached by the cooling agent during operation. For example, the cooling agent tubes may comprise or consist of plastic, such as PEEK, PEK, PPS, PI, PEI, etc. Accordingly, the heat sink 62 is electrically isolated from the hollow conductors 48, 50 due to the cooling agent tubes 66, 68 being electrically insulating.

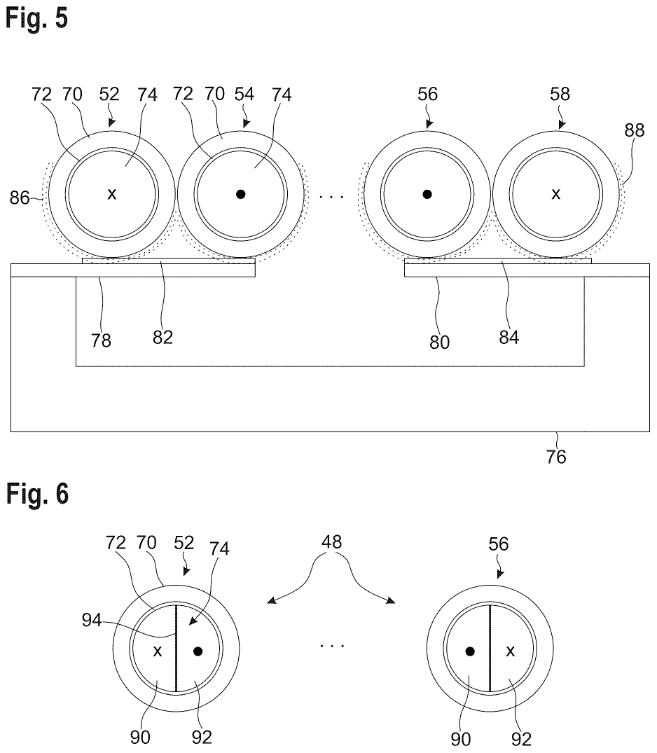

FIG. 5 shows a cross section through the hollow conductors 48, 50, wherein only the first end portions 52, 54 and the second end portions 56, 58 are shown. In this embodiment, the hollow conductors 48, 50 each have a circular cross section. However, it is to be understood that the hollow conductors 48, 50 may alternatively have any other suitable cross section, e.g. a rectangular cross section, a quadratic cross section, a hexagonal cross section, an elliptic cross section, etc.

As is illustrated in FIG. 5, the hollow conductors 48, 50 each comprise a conductive layer 70, e.g. a wall, for example an outer wall. The conductive layer 70 may comprise or consist of any suitable electrically conductive material. Therein, an electrically conductive material may be chosen that has both high electrical conductivity and thermal conductivity.

For example, the electrically conductive material may comprise at least one electrically conductive metal. Therein, a metal or metal alloy having both high electrical conductivity and thermal conductivity may be used, for example copper.

As another example, the at least one electrically conductive material comprises at least one electrically conductive non-metallic material, wherein a non-metallic material or combination of materials having both high electrical conductivity and thermal conductivity may be used. Therein, the at least one electrically conductive non-metallic material is diamagnetic or paramagnetic. Accordingly, the at least one electrically conductive non-metallic material is not ferromagnetic, and has low magnetic permeability.

In an embodiment, the conductive layer 70 may have at least a predetermined thickness, for example at least five times the skin depth of an RF signal having the lowest frequency (corresponding to the highest skin depth) to be processed by the impedance matching network 20.

Optionally, a protective layer 72 may be provided on the inner surface of the conductive layer 70. In an embodiment, the protective layer 72 may be coated onto the conductive layer 70, e.g. from the inside. Alternatively, the protective layer 72 may be provided first, and the conductive layer 70 may be coated onto the protective layer 72.

In general, a material having chemical resistance to the cooling agent to be used may be chosen for the protective layer 72. Further, a material having high thermal conductivity may be chosen for the protective layer 72. For example, the protective layer 72 comprises at least one of plastic, stainless steel, or lacquer. However, it is to be understood that any other suitable type of material may be used for the protective layer 72.

In an embodiment, the hollow conductors 48, 50 each have a hollow interior 74 that is confined by the conductive layer 70 or, if present, by the protective layer 72. The liquid cooling agent flows through this hollow interior 74, as is indicated by the dots and “X”.

FIG. 5 also illustrates an example of how the hollow conductors 48, 50 are electrically connected to the impedance matching network 20, for example to the impedance matching circuit 34. In this embodiment, the impedance matching network 20, for example the impedance matching circuit 34, comprises a structure 76 as well as a first strip 78 and a second strip 80 via which the hollow conductors 48, 50 are connected to the structure 76 that is connected with a component to be cooled. The strips 78, 80 may relate to copper strips. In other words, the strips 78, 80 may be made of copper.

In an embodiment, the first end portions 52, 54 are soldered to the first strip 78, i.e. the first end portions 52, 54 are electrically connected to the first strip 78 by a soldering layer 82. Likewise, the second end portions 56, 58 are soldered to the second strip 80, i.e. the second end portions 56, 58 are electrically connected to the second strip 80 by a soldering layer 84.

Alternatively or additionally, a first strip or wire 86 may be clamped to the first end portions 52, 54, and a second strip or wire 88 may be clamped to the second end portions 56, 58. The first strip or wire 86 is electrically connected with the first strip 78, while the second strip or wire 88 is electrically connected with the second strip 80.

In any embodiment, the first fluid port 40 and the second fluid port 42 are both arranged on the same side of the hollow conductors 48, 50, namely at the first end portions 52, 54 of the hollow conductors 48, 50, which is the side having the lower potential difference to the common reference potential.

Put differently, the fluid connections to the hollow conductors 48, 50 are arranged at the same side of the hollow conductors 48, 50, namely at the first end portions 52, 54, while the electrical connections to the hollow conductors 48, 50 are arranged at different sides of the hollow conductors 48, 50, namely at the first end portions 52, 54 and at the second end portions 56, 58.

In an embodiment, the first end portions 52, 54 may be electrically connected to the strip having the lower potential, namely the first strip 78 in the exemplary embodiment shown in FIG. 5.

A further embodiment of the liquid-cooled conductor structure 38 is shown in FIG. 6, wherein only the differences compared to the embodiment described above are explained hereinafter. In this example embodiment, the liquid-cooled conductor structure 38 comprises only a single hollow conductor 48.

In an embodiment, the hollow interior 74 of the hollow conductor 48 is divided into a first interior portion 90 and a second interior portion 92 by a separating wall 94. The separating wall 94 fluidly separates the first interior portion 90 from the second interior portion 92 along the entire length of the hollow conductor 48.

In this embodiment, the first fluid port 40 is fluidly connected to the first interior portion 90 at the first end portion 52, while the second fluid port 42 is fluidly connected to the second interior portion 92 at the first end portion 52. At the second end portion 52, the fluid redirecting portion 60 fluidly connects the first interior portion 90 with the second interior portion 92. Accordingly, the hollow conductor 48 provides two separate fluid path portions, wherein the fluid path portions are separated by the separating wall 94.

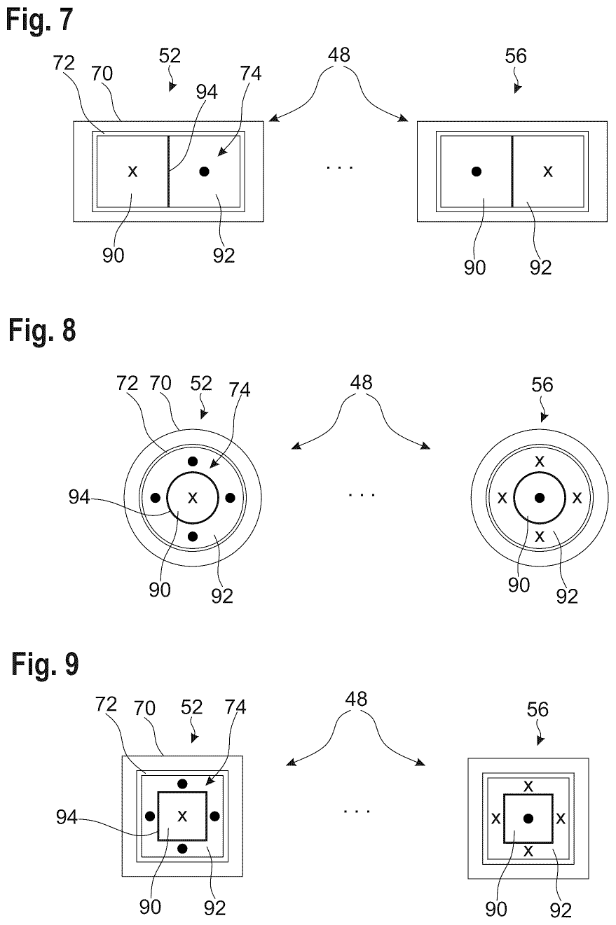

In FIG. 7, another embodiment is shown that distinguishes from the one of FIG. 6 by its shape. In an embodiment, the hollow conductor 48 has a rectangular cross section such that the hollow interior 74 also has a rectangular cross section. Consequently, the first interior portion 90 and the second interior portion 92, which are obtained due to the separating wall 94, also each have a rectangular cross section.

In FIG. 8, another embodiment is shown that differs from the one shown in FIG. 6 in that the separating wall 94 is shaped differently, namely cylindrically, for example with a defined radius. Hence, the first interior portion 90 is encircled by the second interior portion 92. In other words, both interior portions 90, 92 are arranged in a coaxial manner. For instance, the separating wall 94 may be established by a pipe, a tube, a sleeve or a hose that is inserted into the hollow conductor 48, thereby providing the first interior portion 90 as well as the second interior portion 92.

In an embodiment, the separating wall 94, which is located within the hollow conductor 48, may be made of an electrically conductive material, e.g. a metal, or an electrically non-conductive material, e.g. a plastic material.

In FIG. 9, another embodiment is shown that differs from the one shown in FIG. 8 in that the shape is different, as the hollow conductor 48 has a rectangular, for example quadratic, cross section rather than a cylindrical cross section. Consequently, the separating wall 94 also has a rectangular, for example quadratic, cross section, resulting in differently shaped interior portions 90, 92.

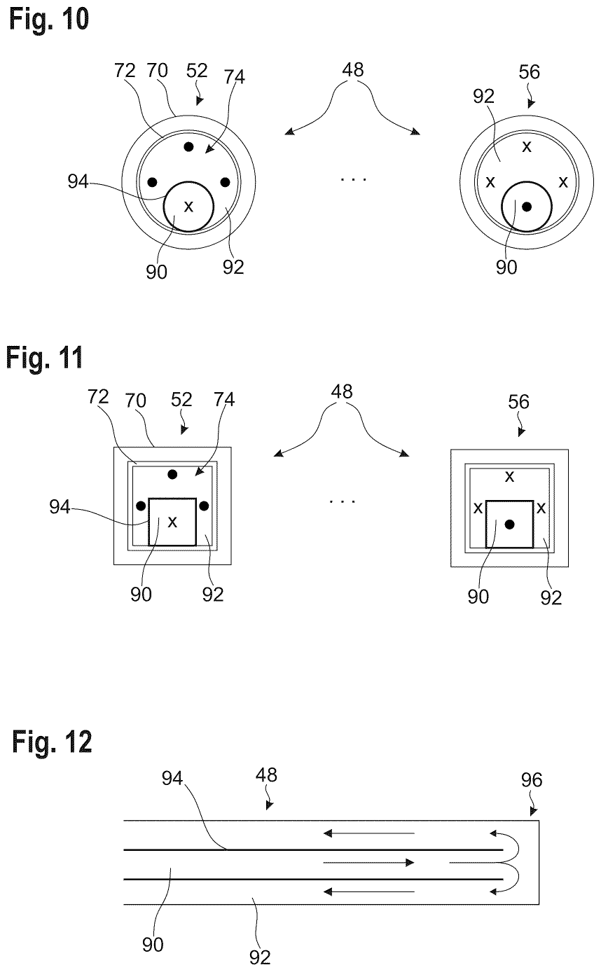

In FIG. 10, another embodiment is shown that differs from the one shown in FIG. 8 in that the cylindrically shaped interior portions 90, 92 are not located coaxial with respect to each other, but offset. In an embodiment, the separating wall 94, separating the first interior portion 90 from the second inter portion 92, may contact the conductive layer 70 (or the protective layer 72 if present) as shown. However, the cylindrically shaped interior portions 90, 92 may also be located in a non-coaxial manner while the separating wall 94 is not in contact with the conductive layer 70 (or the protective layer 72 if present).

In FIG. 11, another embodiment is shown that differs from the one shown in FIG. 9 in that the rectangular shaped interior portions 90, 92 are not located to have a common center, but offset with regard to their centers. In an embodiment, the separating wall 94, separating the first interior portion 90 from the second inter portion 92, may contact the conductive layer 70 (or the protective layer 72 if present) as shown. However, the interior portions 90, 92 may also be located offset with respect to each other while the separating wall 94 is not in contact with the conductive layer 70 (or the protective layer 72 if present).

In FIG. 12, a cross sectional view along the hollow conductor 48 is shown, for example at its second end portion 56, 58, namely the portions connected to the redirecting portion 60 in FIG. 3.

Instead of using the separately formed redirecting portion 60, the separating wall 94 may be shorter than the conductive layer 70 (or the protective layer 72 if present), thereby providing an internal redirecting section 96 as shown in FIG. 12. In other words, the wall encompassing the first interior portion 90 is shorter than the wall encompassing the second inter portion 92, thereby establishing the internal redirecting section 96.

In an embodiment, the internal redirecting section 96 as shown in FIG. 12 may apply to any (or all) of the embodiments shown in FIGS. 8-11.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (A SIC), a field programmable gate array (FPGA) , a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the plasma control system 10 referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuity to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuity disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A liquid-cooled conductor structure for a radio frequency, RF, plasma impedance matching network,
wherein the liquid-cooled conductor structure comprises at least one hollow conductor that comprises an electrically conductive material,
wherein the at least one hollow conductor has a first end portion and a second end portion, wherein the first end portion is electrically connectable to the impedance matching network, and wherein the second end portion is electrically connectable to the impedance matching network,
wherein the liquid-cooled conductor structure has a first fluid port and a second fluid port that are both fluidly connected to the at least one hollow conductor, such that the liquid-cooled structure is configured to allow a liquid cooling agent to flow through the first fluid port, the at least one hollow conductor, and the second fluid port,
wherein the at least one hollow conductor provides at least two separate fluid path portions for the liquid cooling agent, and
wherein both the first fluid port and the second fluid port are arranged at the first end portion of the at least one hollow conductor.

2. The liquid-cooled conductor structure of claim 1, wherein the at least one hollow conductor establishes an inductance.

3. The liquid-cooled conductor structure of claim 1, wherein the liquid-cooled conductor structure comprises at least two separately formed hollow conductors that are arranged in parallel.

4. The liquid-cooled conductor structure of claim 1, wherein the at least one hollow conductor comprises a separating wall within the at least one hollow conductor for establishing the separate fluid path portions.

5. The liquid-cooled conductor structure of claim 4, wherein the separating wall is shorter than an outer wall of the hollow conductor, thereby establishing an internal redirecting section that connects both separate fluid path portions with each other.

6. The liquid-cooled conductor structure of claim 1, wherein the electrically conductive material comprises at least one electrically conductive metal.

7. The liquid-cooled conductor structure of claim 6, wherein the at least one electrically conductive metal comprises copper.

8. The liquid-cooled conductor structure of claim 1, wherein the at least one electrically conductive material comprises at least one electrically conductive non-metallic material.

9. The liquid-cooled conductor structure of claim 8, wherein the at least one electrically conductive non-metallic material is diamagnetic or paramagnetic.

10. The liquid-cooled conductor structure of claim 1, wherein an inner surface of a wall of the at least one hollow conductor comprises a protective layer.

11. The liquid-cooled conductor structure of claim 10, wherein the protective layer comprises at least one of plastic, stainless steel, or lacquer.

12. A radio frequency, RF, plasma impedance matching system, the RF plasma impedance matching system comprising an RF plasma impedance matching
network,
wherein the RF plasma impedance matching network comprises an input port being connectable to a radio frequency, RF, generator circuit,
wherein the RF plasma impedance matching network further comprises an output port being connectable to a load,
wherein the RF plasma impedance matching network further comprises a transmission circuit, wherein the transmission circuit connects the output port to the input port, and
wherein the RF plasma impedance matching network comprises at least one liquid-cooled conductor structure according to claim 1.

13. The RF plasma impedance matching system of claim 12, further comprising an RF generator circuit, wherein the RF generator circuit comprises a heat sink, wherein the impedance matching system further comprises a first cooling agent tube being connected to the first fluid port and a second cooling agent tube being connected to the second fluid port, and wherein at least one of the first cooling agent tube or the second cooling agent tube is directly connected to the heat sink.

14. The RF plasma impedance matching system of claim 13, wherein the first cooling agent tube and the second cooling agent tube each consist of an electrically isolating material at least partially.

15. The RF plasma impedance matching system of claim 13, wherein the RF plasma impedance matching system further comprise at least one electrical isolator, wherein the at least one electrical isolator is configured to electrically isolate the at least one hollow conductor from the heat sink.

16. The RF plasma impedance matching system of claim 12, wherein the RF plasma impedance matching network comprises a housing, wherein the transmission circuit is arranged within the housing.

17. The RF plasma impedance matching system of claim 16, wherein the housing is fully closed.

18. The RF plasma impedance matching system of claim 17, wherein the housing is air-tight.

19. The RF plasma impedance matching system of claim 12, wherein the at least one hollow conductor is electrically connected to the transmission circuit via clamping of a strip or wire of the transmission circuit to the at least one hollow conductor.

20. The RF plasma impedance matching system of claim 12, wherein the at least one hollow conductor is electrically connected to the transmission circuit via soldering of a strip or wire of the transmission circuit to the at least one hollow conductor.

21. The RF plasma impedance matching system of claim 12, wherein the first fluid port and the second fluid port both are arranged at a side of the liquid-cooled conductor structure having a lower potential difference to a reference potential.
